(19) United States
(12) Patent Application Publication
(10) Pub. No.: US 2025/0364280 A1
(43) Pub. Date: Nov. 27, 2025

(54) LASER ANNEALING DEVICE AND LASER ANNEALING METHOD USING THE SAME

(71) Applicant: Samsung Display Co., LTD., Yongin-si (KR)

(72) Inventors: DONG-MIN LEE, Yongin-si (KR); JI-HWAN KIM, Yongin-si (KR); JONGOH SEO, Yongin-si (KR); DONGGYU JIN, Yongin-si (KR)

(21) Appl. No.: 19/017,146

(22) Filed: Jan. 10, 2025

(30) Foreign Application Priority Data
May 21, 2024 (KR) 10-2024-0065539

(51) Int. Cl. H01L 21/67; H01L 21/268

(52) U.S. Cl. CPC H01L 21/67115; H01L 21/268

(57) ABSTRACT

A laser annealing device includes: a controller configured to form a pulse profile sequentially including a first peak having a first intensity, a second peak having a second intensity greater than the first intensity, and a third peak having a third intensity between the first intensity and the second intensity by selecting an output time of a plurality of pulses such that the plurality of pulses overlap in the output time; and a laser generator configured to sequentially output the plurality of pulses.

This application claims priority to Korean Patent Application No. 10-2024-0065539, filed on May 21, 2024, and all the benefits accruing therefrom under 35 U.S.C. § 119, the content of which in its entirety is herein incorporated by reference.

### BACKGROUND

### 1. Field

Embodiments relate to a laser annealing device and a laser annealing method using the same. More particularly, embodiments relate to the laser annealing device using a solid laser and the laser annealing method using the same

### 2. Description of the Related Art

In a manufacturing process of a display device, a dehydrogenation process and an annealing process may be performed. The display device may include an insulating layer and an active layer sequentially stacked on a substrate. The active layer may include amorphous silicon. The amorphous silicon may be annealed through the annealing process.

The dehydrogenation process may be performed before the annealing process to reduce the hydrogen content of the active layer. An insulating layer may be a high hydrogen thin film (i.e., the insulating layer may have a greater hydrogen content than other layers included in the display device). The hydrogen included in the insulating layer may not be escape to outside during the dehydrogenation process. The hydrogen that has not escape to the outside may diffuse to the active layer. Accordingly, defects such as film bursting may occur on a surface of the active layer.

### SUMMARY

Embodiments provide a laser annealing device with an improved process margin.

Other embodiments provide a laser annealing method using the laser annealing device.

A laser annealing device according to an embodiment includes: a controller configured to form a pulse profile sequentially including a first peak having a first intensity, a second peak having a second intensity greater than the first intensity, and a third peak having a third intensity between the first intensity and the second intensity by selecting an output time of a plurality of pulses such that the plurality of pulses overlap in the output time; and a laser generator configured to sequentially output the plurality of pulses.

In an embodiment, the laser generator may be provided in plurality, and may be grouped into a first laser group, a second laser group, and a third laser group, and the first laser group may include only one laser generator.

In an embodiment, the first laser group may output a first pulse, the second laser group sequentially may output, following the first pulse, a second pulse, a third pulse, a fourth pulse, a fifth pulse, a sixth pulse, a seventh pulse, and an eighth pulse, the third laser group sequentially may output, following the eighth pulse, a ninth pulse and a tenth pulse, the first peak may be formed by the first pulse, the second peak may be formed by overlapping the second pulse, the third pulse, the fourth pulse, the fifth pulse, the sixth pulse, the seventh pulse, and the eighth pulse in the output time, and the third peak may be formed by overlapping the ninth pulse and the tenth pulse in the output time.

In an embodiment, a time interval between the eighth pulse and the ninth pulse may be greater than 0 and about 12 nanoseconds or less.

In an embodiment, a time interval between the first pulse and the ninth pulse may be about 91 to about 95 nanoseconds, and a time interval between the first pulse and the tenth pulse may be about 101 to about 105 nanoseconds

In an embodiment, a time interval between the ninth pulse and the tenth pulse may be set to be greater than any of a time interval between two adjacent pulses among the second to eighth pulses.

In an embodiment, an object to be processed by the plurality of pulses may include: a substrate, a first insulating layer disposed on the substrate and having a first hydrogen content, a second insulating layer disposed on the first insulating layer and having a second hydrogen content smaller than the first hydrogen content, and a preliminary active layer disposed on the second insulating layer and including amorphous silicon.

In an embodiment, a temperature profile of the preliminary active layer corresponding to the pulse profile may include a fourth peak and a fifth peak, a temperature of the fifth peak may be greater than a temperature of the fourth peak, and a temperature of the preliminary active layer may gradually decrease over time starting from the fifth peak.

In an embodiment, the laser generator may include a solid laser medium.

In an embodiment, the plurality of pulses may have the same pulse width and same intensity.

A laser annealing method according to an embodiment includes: forming a pulse profile sequentially including a first peak having a first intensity, a second peak having a second intensity greater than the first intensity, and a third peak having a third intensity between the first intensity and the second intensity by selecting an output time of the plurality of pulses such that a plurality of pulses overlap in the output time; sequentially outputting the plurality of pulses to an object to be processed, which includes amorphous silicon; and annealing the amorphous silicon into polysilicon.

In an embodiment, the first may be formed by a first pulse, the second peak may be formed by overlapping a second pulse, a third pulse, a fourth pulse, a fifth pulse, a sixth pulse, a seventh pulse, and an eighth pulse in the output time, and the third peak may be formed by overlapping a ninth pulse and a tenth pulse in the output time.

In an embodiment, the ninth pulse may be output to have a time interval greater than 0 and less than about 12 nanoseconds from the eighth pulse.

In an embodiment, the ninth pulse may be output to have a time interval of about 91 to about 95 nanoseconds from the first pulse, and the tenth pulse may be output to have a time interval of about 101 to about 105 nanoseconds from the first pulse.

In an embodiment, wherein the object to be processed may include: a substrate, a first insulating layer having a first hydrogen content formed on the substrate, a second insulating layer formed on the first insulating layer and having a second hydrogen content smaller than the first hydrogen content, and a preliminary active layer formed of the amorphous silicon on the second insulating layer.

In an embodiment, the first insulating layer may be formed of silicon nitride, and the second insulating layer may be formed of silicon oxide.

In an embodiment, a time interval between the ninth pulse and the tenth pulse may be set to be greater than any of a time interval between two adjacent pulses among the second to eighth pulses.

In an embodiment, the forming of the pulse profile may include: the first intensity and the third intensity may be selected to correspond to a temperature less than a melting temperature of the amorphous silicon, and the second intensity may be selected to correspond to a temperature greater than the melting temperature of the amorphous silicon.

In an embodiment, the plurality of pulses may be generated using a solid laser medium.

In an embodiment, the plurality of pulses may be set to have the same pulse width and same intensity.

The laser annealing device and the laser annealing method using the same according to the embodiments may form a pulse profile sequentially including a first peak having a first intensity, a second peak having a second intensity greater than the first intensity, and a third peak having a third intensity between the first intensity and the second intensity by selecting an output time of the plurality of pulses so that a plurality of pulses overlap. The plurality of pulses may sequentially output to an object to be processed including amorphous silicon. The first peak may induce dehydrogenation in the object to be processed, and the second peak and the third peak may prevent stain during the annealing of the amorphous silicon. The third peak forms the pulse profile adjacent to the second peak, so that a peak temperature of the amorphous silicon may be largest at the second peak, and the peak temperature of the amorphous silicon may gradually decrease over time from the second peak. Accordingly, the film bursting defects of the active layer may be effectively prevented.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a block diagram illustrating a laser annealing device according to an embodiment of the disclosure.

FIG. 2 is a view illustrating the pulse profile entered into the laser annealing device of FIG. 1.

FIG. 3 is a view illustrating the plurality of pulses forming the pulse profile of FIG. 2.

FIG. 4 is a view illustrating of a temperature profile according to the pulse profile of FIG. 2.

FIGS. 5, 6, and 7 are views illustrating an effect of the laser annealing device according to an embodiment of the disclosure.

FIGS. 8, 9, 10, 11, 12, 13, 14, 15, and 16 are views illustrating the laser annealing method using the laser annealing device of FIG. 1.

FIG. 17 is a view illustrating a manufacturing method of a display device including the laser annealing method of FIGS. 9, 10, 11, 12, 13, 14, 15, and 16.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value.

Hereinafter, display devices in embodiments will be described in more detail with reference to the accompanying drawings. The same reference numerals are used for the same components in the drawings, and redundant descriptions of the same components will be omitted.

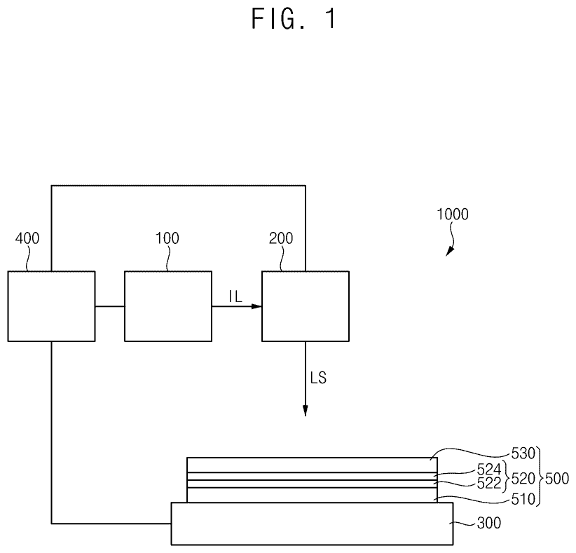

FIG. 1 is a block diagram illustrating a laser annealing device according to an embodiment of the disclosure.

Referring to FIG. 1, a laser annealing device 1000 according to an embodiment of the disclosure may include a laser generator 100, an optical system 200, a stage 300, and a controller 400. Here, the laser annealing device 1000 may be a device capable of performing a laser annealing process.

The laser generator 100 may generate an input light IL. The input light IL may have a predetermined pulse profile. In an embodiment, the laser generator 100 may sequentially output a plurality of pulses forming the pulse profile. In an embodiment, the laser generator 100 may be provided in plurality (i.e., it can generate a plurality of lasers simultaneously). For example, the laser generator 100 may be about 10. However, the disclosure is not limited thereto.

In an embodiment, the laser generator 100 may include a solid laser. For example, the laser generator 100 may be of type Yb:YAG. For example, the laser generator 100 may be doped with ytterbium ions on the solid having a crystalline structure called ytterbium:yttrium-aluminum-garnet. However, the disclosure is not limited thereto.

For example, the laser generator 100 including the solid laser (i.e., SLA) may have an oscillation frequency of about 20 times or more than an oscillation frequency of a gaseous laser (i.e., ELA). For example, the oscillation frequency of the SLA is about 10000 Hz, and the oscillation frequency of the ELA may be about 600 Hz. However, the disclosure is not limited thereto.

For example, a power of the solid laser medium may be about 600 watts (W) and the peak power may be about 720 W. However, the disclosure is not limited thereto.

A laser beam LS may perform a dehydrogenation or an annealing process according to a set energy density value.

The optical system 200 may convert the input light IL of the laser generator 100 into the laser beam LS as at least one output light beam. For example, the laser beam LS may be converted into a line beam to scan the object to be processed 500 disposed on stage 300.

For example, a long axis size of the line beam may be about 1500 millimeters (mm), and a short axis size may be about 80 micrometers (m). However, the disclosure is not limited thereto.

The optical system 200 may be disposed in an optical path of the laser beam LS. The laser annealing device 1000 may further include a plurality of optical systems capable of performing functions independently of the optical system 200. For example, the plurality of optical systems may include a beam splitter capable of split the beam, a mirror capable of convert a beam path (i.e., the optical path), and a galvanometer scanner, or the like.

The stage 300 may provide a flat surface on which an object to be processed 500 may be disposed. The laser annealing device 1000 may further include a driver capable of moving the stage 300. The driver may be disposed under or one side of the stage 300. Accordingly, the stage 300 may move at a constant speed in one direction.

During the laser beam LS is being irradiated, the stage 300 may move in the one direction at the constant speed. However, the disclosure is not limited thereto. For example, the stage 300 may be fixed, and the laser beam LS may move.

The controller 400 may control an operation of the laser generator 100, the optical system 200, and the stage 300.

The controller 400 may control a frequency, a pulse width, pulse duration, or the like, of the laser generator 100. The controller 400 may control a beam profile, an angle, or the like (of the beam) passing through the optical system 200. The controller 400 may control a movement speed, a movement direction, or the like, of the stage 300.

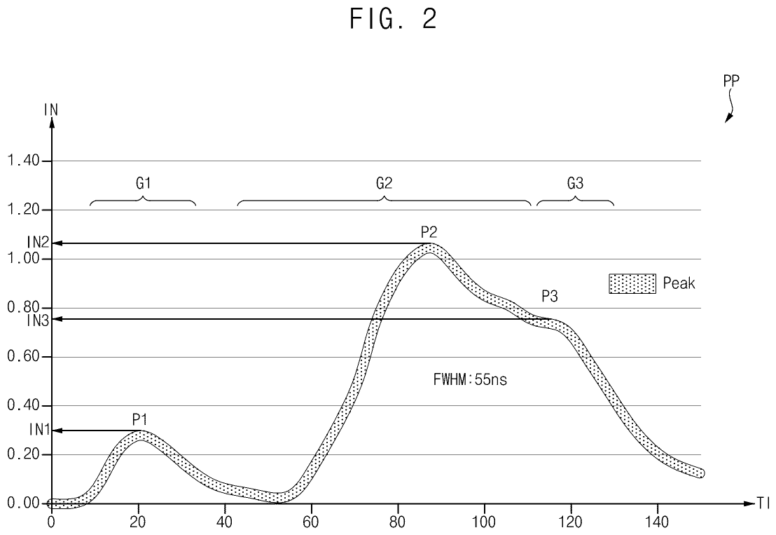

In an embodiment, the controller 400 may set the pulse profile (i.e., pulse shape) of the input light IL. A detailed description of the pulse profile will be provided below with reference to FIG. 2 et seq.

For example, one laser generator 100 may emit the input light IL having the pulse profile including a Gaussian peak.

For another example, the plurality of input lights IL emitted from the plurality laser generators 100 may generate various pulse profiles by applying a time delay called a sync offset.

However, the disclosure is not limited thereto, and the controller 400 may control various operations of the laser generator 100, the optical system 200 and the stage 300.

In an embodiment, the object to be processed 500 may include a substrate 510, an insulating layer 520, and a preliminary active layer 530.

The substrate 510 may include a flexible material or a rigid material. For example, the flexible material may include a polymeric such as polyimide (“PI”). In addition, the rigid material may include a glass, or the like.

The insulating layer 520 may be disposed on the substrate 510. For example, the insulating layer 520 may include silicon oxide (“SiₓO_{y}”), silicon nitride (“SiₓN_{y}”), silicon oxynitride (“SiOₓN_{y}”), silicon oxycarbide (“SiOₓC_{y}”), silicon carbonitride (SiCₓN_{y}”), aluminum oxide (“AlₓO_{y}”), aluminum nitride (“AlₓN_{y}”), tantalum oxide (“TaₓO_{y}”), hafnium oxide (“HfₓO_{y}”), zirconium oxide (“ZrₓO_{y}”), titanium oxide (“TiₓO_{y}”), and the like, or a combination thereof. These may be used alone or in combination with each other.

In an embodiment, the insulating layer 520 may have a multi-layer structure. For example, the insulating layer 520 may include a first insulating layer 522 and a second insulating layer 524. The first insulating layer 522 may be disposed on the substrate 510, and the second insulating layer 524 may be disposed on the first insulating layer 522.

In an embodiment, the first insulating layer 522 includes the silicon nitride, and the second insulating layer 524 may include the silicon oxide. The first insulating layer 522 and the second insulating layer 524 may have different hydrogen content. In an embodiment, the first insulating layer 522 has a first hydrogen content, and the second insulating layer 524 may have a second hydrogen content smaller than the first hydrogen content.

In an embodiment, the preliminary active layer 530 may be disposed on the insulating layer 520. For example, the preliminary active layer 530 may include amorphous silicon (“a-Si”).

The laser beam LS generated from the laser generator 100 may be directed to irradiate the object to be processed 500 disposed on stage 300. Accordingly, the amorphous silicon may be annealed into polysilicon.

For example, as the solid laser has a high oscillation frequency, heat may accumulate in the substrate 510. As the heat accumulates, the diffusion of hydrogen gas in the first insulating layer 522 may increase.

The hydrogen gas may diffuse through the second insulating layer 524 to the active layer in which the preliminary active layer 530 is annealed. At this time, a hydrogen movement velocity may be reduced at an interface between the second insulating layer 524 and the preliminary active layer 530. Accordingly, a hydrogen bubble which the hydrogen gas accumulates may be formed in the annealed active layer.

When the hydrogen bubble bursts, the annealed active layer may burst. The film bursting defect of the annealed active layer may occur (hereinafter, referred to as “film bursting defect” for convenience of explanation). Defects (e.g., dark spot in the display device or the like) may occur due to the film bursting defect.

The laser annealing device 1000 of FIG. 1 is illustrative.

For example, components included in the laser annealing device 1000 of FIG. 1 may be variously changed or omitted. For example, optical system 200 may be omitted. In this case, the input light IL may be directly irradiated to the object to be processed 500.

For another example, the laser annealing device 1000 may further include additional other components. For example, the laser annealing device 1000 may include a sensor. For example, the sensor may be a photo diode. The sensor may be disposed in the optical path. The pulse profile may be checked through the sensor.

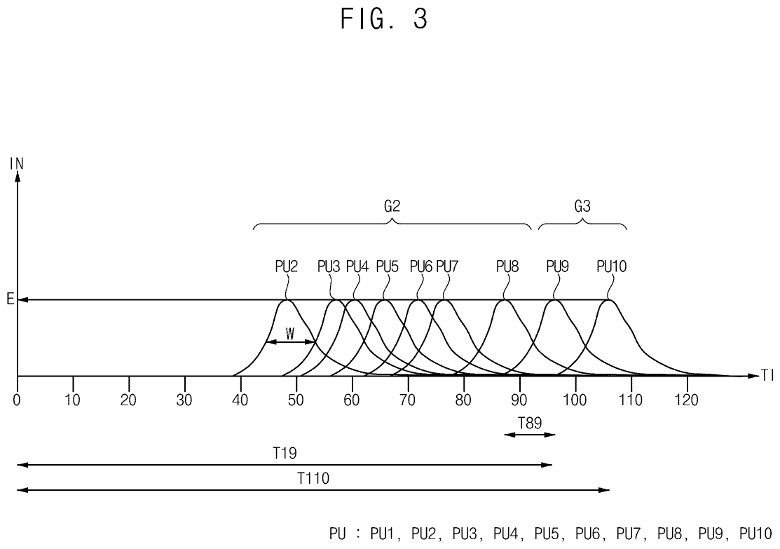

FIG. 2 is a view illustrating the pulse profile entered into the laser annealing device of FIG. 1. FIG. 3 is a view illustrating the plurality of pulses forming the pulse profile of FIG. 2.

For example, in FIGS. 2 and 3, X axis represents time (nanoseconds), and Y axis represents intensity.

Referring to FIGS. 1, 2, and 3, in an embodiment, the controller 400 may form a pulse profile PP sequentially including a first peak P1 with a first intensity IN1, a second peak P2 with a second intensity IN2 greater than the first intensity IN1, and a third peak P3 with a third intensity IN3 between the first intensity IN1 and the second intensity IN2 by selecting an output time TI of the plurality of pulses PU so that the plurality of pulses PU overlap in the output time TI. In other words, the first peak P1 has a smallest peak occurrence time, and the second peak P2 and the third peak P3 may occur sequentially after the first peak P1. In an embodiment, a full width at half maximum (“FWHM”) may be 55 nanoseconds.

In an embodiment, the laser generator 100 may be provided in plurality. For example, the number of the laser generator 100 may be about 10. In this case, the laser generator 100 may be grouped into a first laser group, a second laser group, and a third laser group. In an embodiment, the first laser group may include only one laser generator 100. The second laser group may include about seven laser generators 100. The third laser group may include about two laser generators 100. However, the disclosure is not limited thereto.

For example, a size of the line beam may be about 1500 mm (length) by about 80 micrometers (width). An energy density required for the annealing may be reduced by about 435 millijoules (mJ) per unit area (unit: square centimeter). About ten laser generators 100 may be used to obtain the energy required for the annealing. However, the disclosure is not limited thereto.

In an embodiment, the plurality of pulses PU may have the same pulse width W and the same intensity E. In this case, the plurality of laser generators 100 may be set up in the same way to facilitate process control. For example, as the process progresses with the same settings, it may have a stability of energy change. However, the disclosure is not limited thereto.

In an embodiment, the first laser group may output a first pulse PU1. For example, in FIG. 3, the output time of the second to tenth pulses PU2, PU3, PU4, PU5, PU6, PU7, PU8, PU9, and PU10 may be determined based on the output time of the first pulse PU1 (i.e., the output time of the first pulse PU1 may set to about 0 seconds). In an embodiment, the first peak P1 (e.g., pulses of the first group G1) may be formed by the first pulse PU1.

In an embodiment, the first peak P1 may induce dehydrogenation in the object to be processed 500. By inducing the dehydrogenation before the annealing, the film bursting defect may be further prevented.

An energy required for the dehydrogenation may be less than an energy required for annealing. Thus, in an embodiment, the pulses of the first group G1 may include only one pulse (i.e., only the one laser generator 100).

In the case of a laser annealing device according to a comparative embodiment, the plurality of pulses may be included in the pulses of the first group G1. In this case, the annealing may occur first before inducing the dehydrogenation, and the hydrogen content might not be sufficiently low. Accordingly, the film bursting defect may occur.

However, in an embodiment, the second laser group may sequentially output a second pulse PU2, a third pulse PU3, a fourth pulse PU4, a fifth pulse PU5, a sixth pulse PU6, a seventh pulse PU7, and an eighth pulse PU8 following the first pulse PU1. In an embodiment, the second peak P2 may be formed by overlapping the second pulse PU2, the third pulse PU3, the fourth pulse PU4, the fifth pulse PU5, the sixth pulse PU6, the seventh pulse PU7, and the eighth pulse PU8 (e.g., pulses of the second group G2) in the output time TI.

For example, from the first pulse PU1, the second pulse PU2 has a time interval of about 48 nanoseconds (e.g., 46 to 50 nanoseconds), the third pulse PU3 has a time interval of about 58 nanoseconds, the fourth pulse PU4 has a time interval of about 60 nanoseconds, the fifth pulse PU5 has a time interval of about 65 nanoseconds, the sixth pulse PU6 has a time interval of about 71 nanoseconds, the seventh pulse PU7 has a time interval of about 76 nanoseconds, and the eighth pulse PU8 may have a time interval of about 85 nanoseconds (e.g., 83 to 87 nanoseconds). However, the disclosure is not limited thereto. As used herein, the time interval between two pulses are measured as time interval between peaks of the two pulses.

The amorphous silicon included in the object to be processed 500 may be generated by overlapping the second pulse PU2, the third pulse PU3, the fourth pulse PU4, the fifth pulse PU5, the sixth pulse PU6, the seventh pulse PU7, and eighth pulse PU8 (e.g., the pulses of the second group G2) in the output time TI emitted from about seven laser generators 100 to obtain the energy required for the annealing.

In an embodiment, the third laser group may sequentially output the ninth pulse PU9 and the tenth pulse PU10 following the eighth pulse PU8. In an embodiment, the third peak P3 may be formed by the overlapping of the ninth pulse PU9 and the tenth pulse PU10 (pulses of the third group G3) in the output time TI.

In an embodiment, a time interval T19 between the first pulse PU1 and the ninth pulse PU9 may be about 91 to about 95 nanoseconds, and a time interval T110 between the first pulse PU1 and the tenth pulse PU10 may be about 101 to about 105 nanoseconds.

The laser beam LS may scan the object to be processed 500 in a form of the line beam. In this case, as the laser beam scans in the form of the line beam, a vertical line stain defect may occur in the display device. In order to minimize or even prevent the occurrence of the vertical line stain defect, an additional shot may be provided to the object to be processed 500. The additional shot may be smaller than the second intensity IN2 and larger than the first intensity IN1 in order to reduce the occurrence of the vertical line stain defect without contributing to the annealing.

In summary, the first intensity IN1 may be sufficient to induce the dehydrogenation in the object to be processed 500, the third intensity IN3 may be sufficient to reduce the vertical line stain defect in the object to be processed 500, and the second intensity IN2 may be sufficient as long as the object to be processed 500 is annealed. Thus, the first intensity IN1, the third intensity IN3, and the second intensity IN2 may also have large values in that order.

As shown in FIG. 3, the pulse profile PP may be formed by the plurality of pulses.

The time interval between two adjacent pulses among the plurality of pulses PU included in the pulses of the first group G1, the pulses of the second group G2, and the pulses of third group G3 may be different from each other.

In an embodiment, as shown in FIG. 3, the time interval between the ninth pulse PU9 and the tenth pulse PU10 may be greater than any time interval between two adjacent pulses of the second to eighth pulses PU2, PU3, PU4, PU5, PU6, PU7, and PU8.

For example, the pulses of the second group G2 may have a small interval between adjacent pulses for the annealing. The pulses of the third group G3 may be relatively greater than the interval between the adjacent pulses of the second group G2 in order to reduce cooling and the occurrence of the vertical line stain defect.

In an embodiment, a time interval T89 between the eighth pulse PU8 and the ninth pulse PU9 may be greater than 0 and about 12 nanoseconds or less.

In the case of the laser annealing device according to the comparative embodiment, the time interval T89 between the eighth pulse PU8 and the ninth pulse PU9 exceeds about 12 nanoseconds. In this case, a peak temperature of the first insulating layer 522 was reduced to less than about 650 degrees in Celsius (C°), and a temperature duration at about 690 or more degrees in Celsius (a temperature at which no stain defect occur) was reduced to less than about 40 nanoseconds (e.g., zero second), so that an annealing margin was reduced to less than about 10 mJ. The annealing margin may mean an energy interval in which the vertical line stain defect does not occur. A process of controlling may be difficult as the annealing margin is small because the energy must be finely adjusted.

However, in the case of the laser annealing device 1000 according to the embodiment of the disclosure, the time interval T89 between the eighth pulse PU8 and the ninth pulse PU9 may be greater than 0 and about 12 nanoseconds or less. In this case, the peak temperature of the first insulating layer 522 increases to about 650 or more degrees in Celsius (C°), and the temperature duration at about 690 or more degrees in Celsius (the temperature at which no stain defect occur) increases to about 40 nanoseconds or more, and the annealing margin had been increased to about 10 millijoules or more. As the annealing margin becomes greater, the process of controlling may be easier than the process of controlling of the laser annealing device according to the comparative embodiment.

In an embodiment, the time interval T19 between the first pulse PU1 and the ninth pulse PU9 may be about 91 to about 95 nanoseconds, and the time interval T110 between the first pulse PU1 and the tenth pulse PU10 may be about 101 to about 105 nanoseconds.

In the case of the laser annealing device according to the comparative embodiment, the time interval T19 between the first pulse PU1 and the ninth pulse PU9 may be about 105 nanoseconds, and the time interval T110 between the first pulse PU1 and the tenth pulse PU10 may be about 115 nanoseconds. In this case, the peak temperature of the first insulating layer 522 may be less than about 800 degrees in Celsius, and the temperature duration at 690 or more degrees in Celsius may be about 56 nanoseconds. In this case, as the heat accumulates in the first insulating layer 522, the film bursting defect may be occurred. When the object to be processed 500 is tested after processing and destruction, yellowing phenomenon may be found in a rim part of the object to be processed 500, or defects such as the film bursting or the like may be found.

However, in the case of the laser annealing device 1000 according to the embodiment of the disclosure, the time interval T19 between the first pulse PU1 and the ninth pulse PU9 may be about 91 to about 95 nanoseconds, and the time interval T110 between the first pulse PU1 and the tenth pulse PU10 may be about 101 to about 105 nanoseconds. In this case, the peak temperature of the first insulating layer 522 may increase to about 800 degrees in Celsius or more, and the temperature duration at 690 or more degrees in Celsius may be reduced to about 41 nanoseconds. Accordingly, an amount of heat accumulated in the first insulating layer 522 may be reduced, thereby effectively minimizing or even preventing the occurrence of the film bursting defect. In summary, by setting the time interval T89 to be greater than 0 and less than about 12 nanoseconds, the temperature duration at about 690 or more degrees in Celsius may be increased to about 40 nanoseconds or more. Accordingly, the preliminary active layer may be effectively melted. And, by setting the time interval T19 to be about 91 to about 95 nanoseconds and the time interval T110 to be about 101 to about 105 nanoseconds, the temperature duration at 690 or more degrees in Celsius may be reduced to about 41 nanoseconds. Accordingly, the melted layer may be quickly cooled down to prevent the occurrence of the film bursting defect.

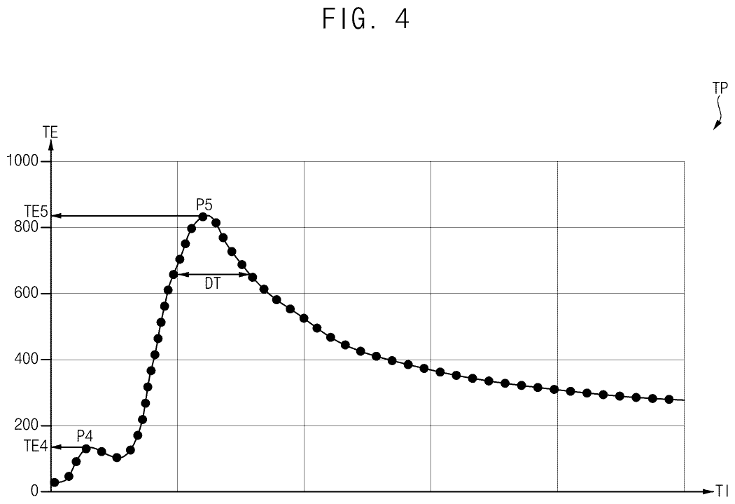

FIG. 4 is a view illustrating of a temperature profile according to the pulse profile of FIG. 2.

For example, in FIG. 4, X axis represents time TI, and Y axis represents the peak temperature of amorphous silicon included in the object to be processed 500.

Referring to FIGS. 1, 2, 3, and 4, in an embodiment, a temperature profile TP of the preliminary active layer 530 corresponding to the pulse profile PP may include a fourth peak P4 and a fifth peak P5 sequentially. A temperature TE5 of the fifth peak P5 may be greater than a temperature TE4 of a fourth peak P4. Starting from the temperature TE5 of the fifth peak P5, the temperature TE of the preliminary active layer 530 may gradually decrease over time TI.

The laser annealing device 1000 according to the embodiment of the disclosure may change the temperature profile TP of the preliminary active layer 530 of FIG. 2 as shown in FIG. 4 by receiving the input of the pulse profile PP.

In the case of the laser annealing device according to the comparative embodiment, three peaks may be found in the temperature profile TP with the pulses of the third group G3 providing the additional shot. For example, if the temperature of the latest peak in the temperature profile TP is the largest by the additional shot, annealing quality may be affected. For example, due to the lack of cooling time, the film bursting defect or the like may occur.

However, in the case of the laser annealing device 1000 according to the embodiment of the disclosure, the pulses of the third group G3 may provide the additional shot adjacent to the pulses of the second group G2. In an embodiment, the time interval T19 between the first pulse PU1 and the ninth pulse PU9 may be about 91 to about 95 nanoseconds, and the time interval T110 between the first pulse PU1 and the tenth pulse PU10 may be about 101 to about 105 nanoseconds. In this case, the temperature TE5 of the fifth peak P5 may be greater than the temperature TE4 of the fourth peak P4 (i.e., the temperature TE5 of the fifth peak P5 may be the largest), and a temperature duration DT at 690 or more degrees in Celsius increases, and the cooling time may be sufficiently taken. Accordingly, the film bursting defect due to the heat accumulating may be effectively minimized or even prevented.

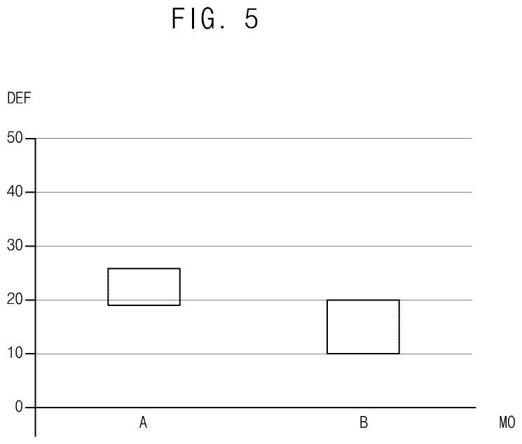

FIGS. 5, 6, and 7 are views illustrating an effect of the laser annealing device according to an embodiment of the disclosure.

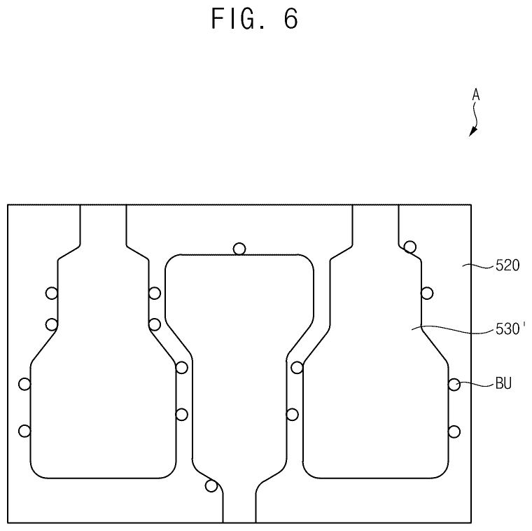

In FIG. 5, X axis represents a model MO, and Y axis represents the number of defective parts. FIGS. 6 and 7 are schematic illustrations of microscopy results by the model MO.

Referring to FIG. 5, model A shows the number of defective products that the film bursting defect occurred after proceeding with the annealing process using the laser annealing device (e.g., gas laser) according to the comparative embodiment. Model B shows the number of defective products that the film bursting defect occurred after proceeding with the annealing process using the laser annealing device (i.e., applying the solid laser and the pulse profile PP of FIG. 2) according to the embodiment of the disclosure.

In the A model, the defective products showed about 20 or more, however, in the B model, less than about 20 defective products showed. Accordingly, yields may be effectively improved.

On the other hand, in the case of the B model according to embodiment, a critical voltage (“VTH”) characteristics that may cause malfunctions in a transistor included in the display device may be improved. As described above, the hydrogen diffusion may decrease as the heat accumulation is reduced in the first insulating layer 522. Accordingly, the critical voltage (“VTH”) characteristics may be effectively improved.

Referring to FIGS. 6, and 7, in the model A, the hydrogen bubble issue occurred and the film bursting defect BU due to the hydrogen bubble was checked.

However, by applying a cumulative temperature reduction pulse profile (e.g., the pulse profile PP of FIG. 2), the diffusion of the hydrogen gas may be reduced in the first insulating layer 522. Accordingly, the occurrence of the hydrogen bubble may be effectively minimized or prevented at the interface between the second insulating layer 524 and the preliminary active layer 530, and the film bursting defect BU may be effectively minimized or prevented by the bursting of the hydrogen bubble.

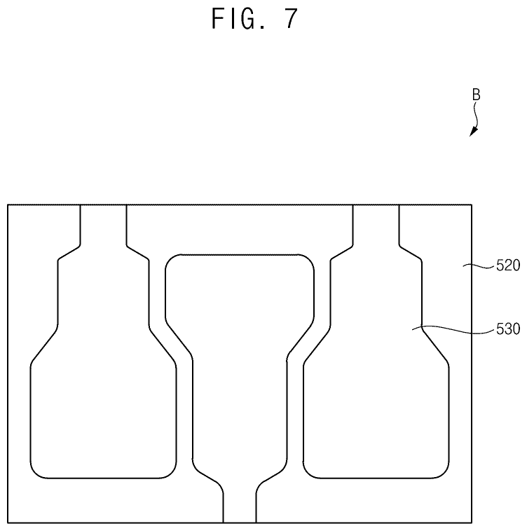

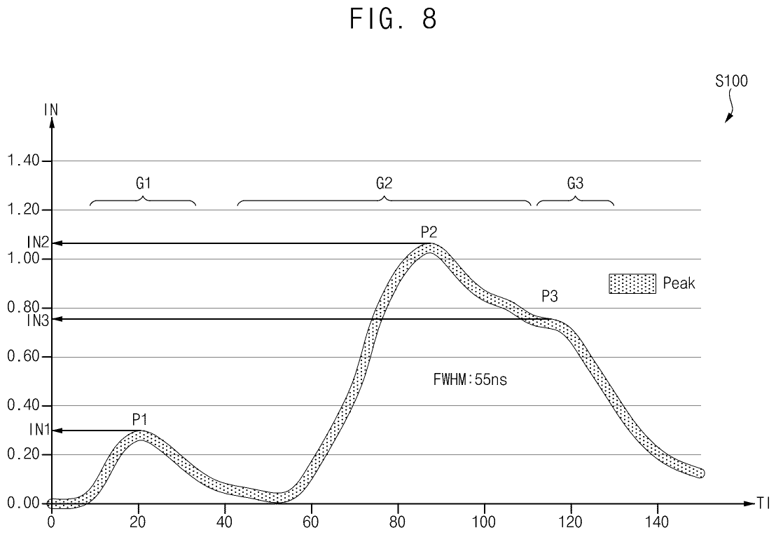

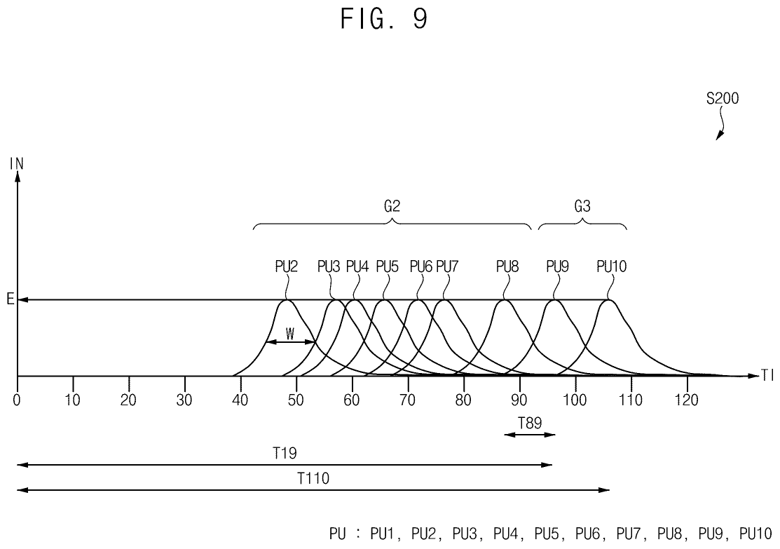

FIGS. 8, 9, 10, 11, 12, 13, 14, 15, and 16 are views illustrating the laser annealing method using the laser annealing device of FIG. 1. FIG. 17 is a view illustrating a manufacturing method of a display device including the laser annealing method of FIGS. 9, 10, 11, 12, 13, 14, 15, and 16.

Hereinafter, overlapping description of the laser annealing device 1000 aforementioned with reference to FIGS. 1, 2, 3, 4, 5, 6, and 7 may be omitted or simplified.

Referring to FIGS. 8 and 9, the pulse profile sequentially including the first peak P1 having the first intensity IN1, the second peak P2 having the second intensity IN2 greater than the first intensity IN1, and the third peak P3 having the third intensity IN3 between the first intensity IN1 and the second intensity IN2 may be formed by selecting the output time TI of the plurality of pulses PU so that the plurality of pulses overlap (S100) in the output time TI.

In an embodiment, the laser generator 100 may include the solid laser. For example, the laser generator 100 may be of type Yb:YAG. However, the disclosure is not limited thereto. As described above, the laser generator 100 including the solid laser (i.e., SLA) may have the oscillation frequency of about 20 times or more than the oscillation frequency of the gas laser (i.e., ELA). For example, the oscillation frequency of the SLA may be about 10000 Hz.

In an embodiment, the laser generator 100 may sequentially output the plurality of pulses forming the pulse profile.

In an embodiment, the plurality of pulses PU may be set to have the same pulse width W and the same intensity E. In this case, the plurality of laser generators 100 may be set up in the same way to facilitate process control. For example, as the process progresses with the same settings, it may have the stability of energy change. However, the disclosure is not limited thereto.

In an embodiment, the laser generator 100 may be provided in plurality. For example, the number of the laser generator 100 may be about 10. In this case, the laser generator 100 may be grouped into the first laser group, the second laser group, and the third laser group. In an embodiment, the first laser group may include only the one laser generator 100. The second laser group may include about seven laser generators 100. The third laser group may include about two laser generators 100. However, the disclosure is not limited thereto.

In an embodiment, the output time TI of the plurality of pulses PU may be selected so that the plurality of pulses PU overlap in the output time TI, the pulse profile PP including the first peak P1 with the first intensity IN1, the second peak P2 with the second intensity IN2 greater than the first intensity IN1, and the third peak P3 with the third intensity IN3 between the first intensity IN1 and the second intensity IN2 may be set. In other words, the first peak P1 has the smallest peak occurrence time, and the second peak P2 and the third peak P3 may occur sequentially after the first peak P1.

In an embodiment, the first laser group may output the first pulse PU1. For example, in FIG. 3, the emission time of the second to tenth pulses PU2˜PU10 may be determined based on the output time of the first pulse PU1 (i.e., the time emitted of the first pulse PU1 is set to about 0 seconds). In an embodiment, the first peak P1 (e.g., the pulses of the first group G1) may be formed by the first pulse PU1.

In an embodiment, the first peak P1 may induce the dehydrogenation of the layer before annealing in the object to be processed 500 to further prevent the film bursting defect.

The energy required for the dehydrogenation may be less than the energy required for the annealing. Thus, in an embodiment, the pulses of the first group G1 may include only one pulse.

In an embodiment, the second laser group may sequentially output the second pulse PU2, the third pulse PU3, the fourth pulse PU4, the fifth pulse PU5, the sixth pulse PU6, the seventh pulse PU7, and the eighth pulse PU8 following the first pulse PU1. In an embodiment, the second peak P2 may be formed by overlapping the second pulse PU2, the third pulse PU3, the fourth pulse PU4, the fifth pulse PU5, the sixth pulse PU6, the seventh pulse PU7, and the eighth pulse PU8 (e.g., the pulses of the second group G2) in the output time TI.

The second pulse PU2, the third pulse PU3, the fourth pulse PU4, the fifth pulse PU5, the sixth pulse PU6, the seventh pulse PU7, and the eighth pulse PU8 emitted from the each of the seven laser generators 100 may be overlapped in the output time TI to obtain the energy required for the annealing.

In an embodiment, the third laser group may sequentially output the ninth pulse PU9 and the tenth pulse PU10 following the eighth pulse PU8. In an embodiment, the third peak P3 may be formed by overlapping the ninth pulse PU9 and the tenth pulse PU10 (the pulses of the third group G3) in the output time TI.

The laser beam LS may scan the object to be processed 500 in the form of the line beam. In this case, as the laser beam is scanned in the form of the line beam, the vertical line stain defect may occur in the display device. In order to minimize or even prevent the occurrence of the vertical line defect, the additional shot may be provided to the object to be processed 500. The additional shot does not contribute to the annealing, in order to reduce the occurrence of the vertical line stain defect, it may be smaller than the second intensity IN2 and greater than the first intensity IN1.

In an embodiment, as shown in FIG. 3, the time interval between the ninth pulse PU9 and the tenth pulse PU10 may be greater than any of a time interval between two adjacent pulses of the second to eighth pulses (PU2, PU3, PU4, PU5, PU6, PU7, and PU8).

For example, the pulses of the second group G2 may have a small interval between adjacent pulses for the annealing. The pulses of the third group G3 may be relatively greater than the interval between the adjacent pulses of the second group G2 in order to reduce the cooling and the occurrence of the vertical line stain defect.

In an embodiment, the time interval T89 between the eighth pulse PU8 and the ninth pulse PU9 may be greater than 0 and about 12 nanoseconds or less.

If the time interval T89 between the eighth pulse PU8 and the ninth pulse PU9 exceeds about 12 nanoseconds, the peak temperature of the first insulating layer (e.g., the first insulating layer 522 of FIG. 1) was decreased, and the temperature duration at about 690 or more degrees in Celsius was reduced, so that the annealing margin may be smaller. The process of controlling may be difficult as the annealing margin is small because the energy must be finely adjusted.

However, in an embodiment, the time interval T19 between the first pulse PU1 and the ninth pulse PU9 may be about 91 to about 95 nanoseconds, and the time interval T110 between the first pulse PU1 and the tenth pulse PU10 may be about 101 to about 105 nanoseconds.

If the time interval T19 between the first pulse PU1 and the ninth pulse PU9 may be less than about 90 nanoseconds, or if the time interval T110 between the first pulse PU1 and the tenth pulse PU10 may be less than about 101 nanoseconds, the problem of super-annealing may occur as the peak temperature becomes higher. On the other hand, if the time interval T19 between the first pulse PU1 and the ninth pulse PU9 exceeds about 95 nanoseconds, or the time interval T110 between the first pulse PU1 and the tenth pulse PU10 exceeds about 101 nanoseconds, the temperature duration at 690 or more degrees in Celsius decreases as the peak temperature decreases, so that heat may accumulate in the first insulating layer 522. Accordingly, the film bursting defect may occur.

However, in an embodiment, in the pulse profile PP, the first intensity IN1 and the third intensity IN3 may be selected to provide a temperature less than the melting temperature of the amorphous silicon, and the second intensity IN2 may be selected to provide a temperature greater than the melting temperature of the amorphous silicon. Accordingly, the dehydrogenation process may be carried out first, then the annealing process may be carried out, and after the annealing process, the occurrence of the vertical line stain defect may be effectively prevented and the cooling time may be increased by the additional shot.

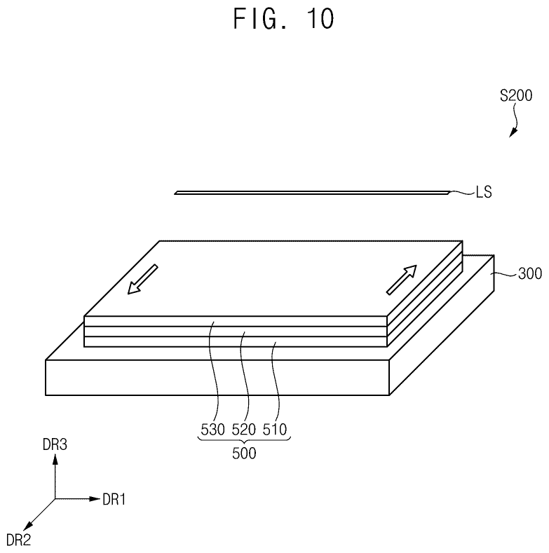

Referring to FIGS. 9 and 10, the plurality of pulses PU may be sequentially output toward the object to be processed 500 including amorphous silicon.

In an embodiment, the object to be processed 500 may include the substrate 510, the insulating layer 520, and the preliminary active layer 530.

In an embodiment, the insulating layer 520 may be disposed on the substrate 510. The insulating layer 520 may have the multi-layer structure. For example, the insulating layer 520 may include the first insulating layer 522 and the second insulating layer 524. The first insulating layer 522 may be disposed on the substrate 510, and the second insulating layer 524 may be disposed on the first insulating layer 522.

In an embodiment, the first insulating layer 522 may include the silicon nitride, and the second insulating layer 524 may include the silicon oxide. The first insulating layer 522 and the second insulating layer 524 may have the different hydrogen content. In an embodiment, the first insulating layer 522 has the first hydrogen content, and the second insulating layer 524 may have the second hydrogen content smaller than the first hydrogen content.

In an embodiment, the preliminary active layer 530 may be disposed on the insulating layer 520. For example, the preliminary active layer 530 may include the amorphous silicon (“a-Si”).

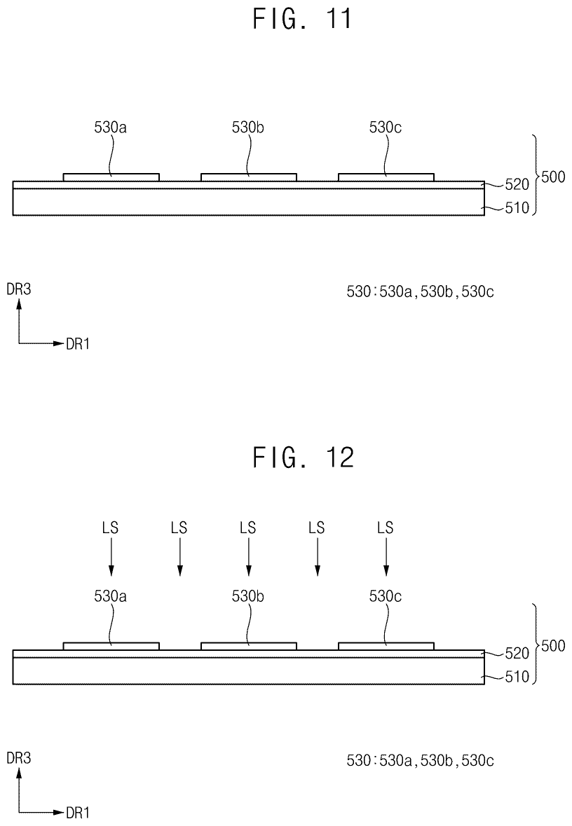

Referring to FIGS. 11, 12, 13, 14, 15, and 16, the amorphous silicon may be annealed into polysilicon.

The laser beam LS may be irradiated to the object to be processed 500 disposed on stage 300. Accordingly, the amorphous silicon may be annealed into the polysilicon.

For example, the solid laser may accumulate the heat on the substrate 510 as the oscillation frequency is large. As the heat accumulates, the diffusion of the hydrogen gas in the first insulating layer 522 may increase.

The hydrogen gas may diffuse through the second insulating layer 524 to the active layer in which the preliminary active layer 530 is annealed. At this time, the hydrogen movement velocity may be reduced at the interface between the second insulating layer 524 and the preliminary active layer 530. Accordingly, the hydrogen bubble which the hydrogen gas accumulates may be formed in the annealed active layer. When the hydrogen bubble bursts, the annealed active layer may burst. The film bursting defect of the annealed active layer may occur. The defects (e.g., the dark spot in the display device or the like) may occur due to the film bursting defect. In order to prevent this, the dehydrogenation process may be carried out first.

As shown in FIG. 10, the laser beam LS may be irradiated to the object to be processed 500 in the form of the line beam. The line beam may have the long axis parallel to a first direction DR1 and the short axis parallel to a second direction DR2 crossing to the first direction DR1. However, the disclosure is not limited thereto.

For example, as stage 300 moves in the second direction DR2, an entire area of the object to be processed 500 may be scanned. However, the disclosure is not limited thereto. For example, first scan may proceed in the second direction DR2 and the second scan may proceed in an opposite direction of the second direction DR2. For example, the dehydrogenation process may be carried out first in the first scan, and then the annealing process may be performed in the second scan. For another example, the stage 300 may be fixed, and a laser beam L2 may move to scan the object to be processed 500.

For example, first scan in the second direction DR2 and the second scan in the opposite direction to the second direction DR2 may proceed by set different energy densities. The energy density may mean the energy intensity falling from a perspective of the object to be processed 500. For example, the laser beam LS may have a first energy density at the first scan, and may have a second energy density at the second scan. The first energy density may be a dehydrogenation energy density, and the second energy density may be an annealing energy density. The annealing energy density may be greater than the dehydrogenation energy density. After the dehydrogenation process is carried out first, by proceeding with the annealing process, the occurrence of the defects due to the accumulation of the heat may be effectively minimized or even prevented.

In an embodiment, the energy densities (e.g., the first energy density and the second energy density) may be set differently depending on a thickness of the preliminary active layer 530. Specifically, the greater the thickness of the preliminary active layer 530, the greater the energy density of the laser beam LS may be set. Here, the thickness is measured in a third direction DR3 which is perpendicular to the first direction DR1 and the second direction DR2.

For example, if the thickness of the preliminary active layer 530 is about 470 Angstrom (A), the dehydrogenation energy density may be set to about 420 millijoules per square centimeters (mJ/cm²), and the annealing energy density may be set to about 593 mJ/cm². For another example, if the thickness of the preliminary active layer 530 is about 500 Å, the dehydrogenation energy density may be set to about 440 mJ/cm², and the annealing energy density may be set to about 618 mJ/cm². However, the disclosure is not limited thereto, and an energy density value may vary depending on a size of the laser beam LS.

Referring to FIG. 11, the insulating layer 520 may be formed on the substrate 510. The preliminary active layer 530 may be formed on the insulating layer 520. For example, the preliminary active layer 530 may include the amorphous silicon. At this time, the substrate 510, the insulating layer 520, and the preliminary active layer 530 may be defined as the object to be processed 500. The preliminary active layer 530 may include a first preliminary active layer 530a, a second preliminary active layer 530b, and a third preliminary active layer 530c may be included.

Referring to FIG. 12, the laser beam LS may be primarily irradiated to the object to be processed 500. Specifically, the laser beam LS may be primarily irradiated to the insulating layer 520 and the preliminary active layer 530 of the object to be processed 500. In other words, the laser beam LS may be primarily irradiated to the insulating layer 520, the first preliminary active layer 530a, the second preliminary active layer 530b, and the third preliminary active layer 530c. Accordingly, a primarily irradiated object to be processed 500′ may be formed.

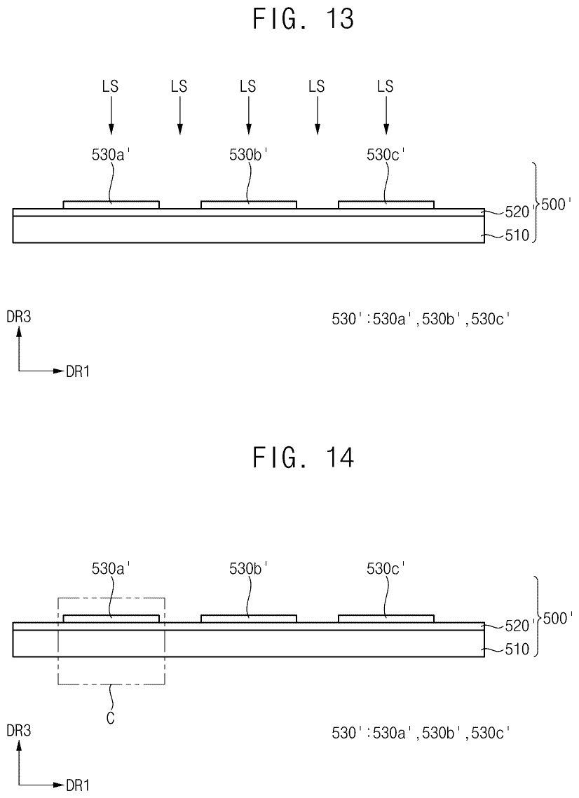

Referring to FIG. 13, the laser beam LS may be secondarily irradiated to primarily irradiated object to be processed 500′. Specifically, the laser beam LS may be secondarily irradiated to a primarily irradiated preliminary active layer 530′. In other words, the laser beam LS may be secondarily irradiated to the first preliminary active layer 530a, the second preliminary active layer 530b, and the third preliminary active layer 530c. Accordingly, a secondarily irradiated object to be processed 500″ may be formed.

The laser beam LS may have the pulse profile (e.g., the pulse profile PP of FIG. 2).

As described above, by setting the pulse profile, the occurrence of defects by the accumulation of the heat may be minimized or even prevented, and the annealing uniformity may be enhanced.

By first proceeding dehydrogenation process using the laser beam LS and then proceeding the annealing process, so that the film bursting defect may be minimized.

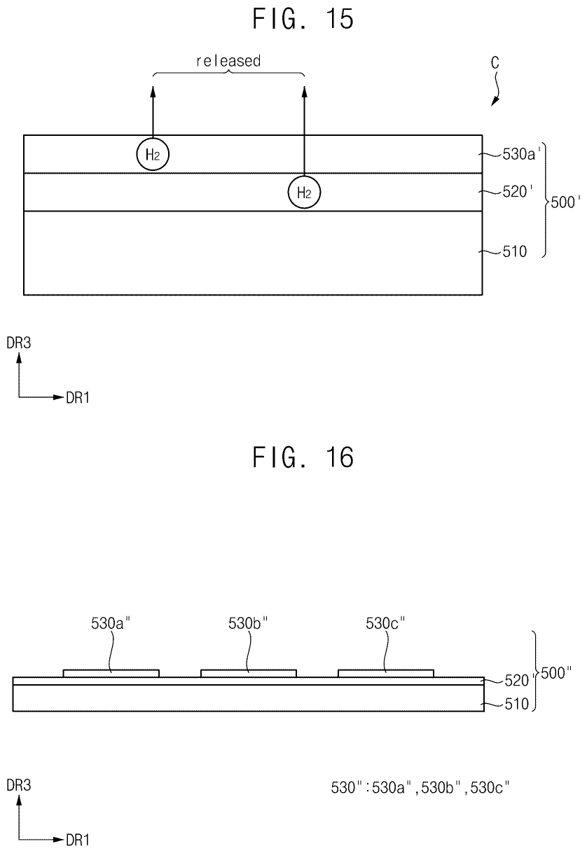

Referring to FIGS. 14 and 15, hydrogen (H2) may be released from the insulating layer 520′ and the preliminary active layer 530′. After lowering the hydrogen content of the insulating layer 520′ and the preliminary active layer 530′, and then proceeding the annealing process may minimize or even prevent the occurrence of defects such as the film bursting.

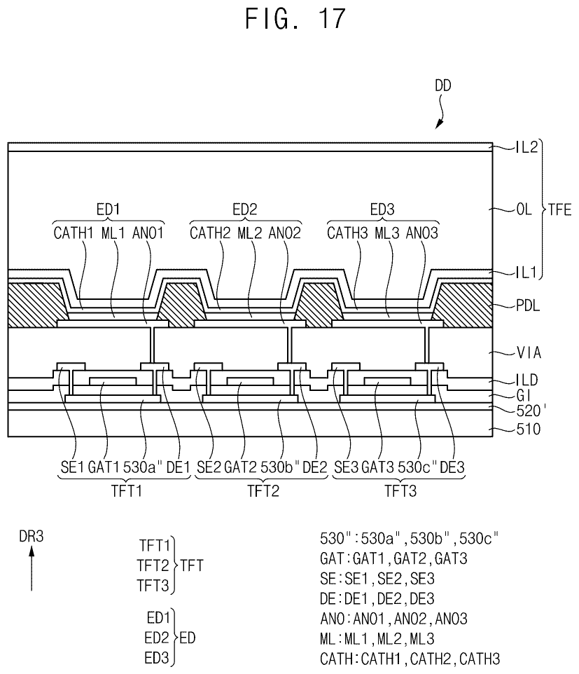

Referring to FIGS. 14 and 16, the object to be processed 500″ in which the annealing process has been completed may include an active layer 530″ including polysilicon. That is, by means of the laser beam LS, the preliminary active layer 530′ including the amorphous silicon may be annealed to become the active layer 530″ including the polysilicon.

Hereinafter, the manufacturing method of the display device DD proceeding after the annealing process using the laser beam LS may be described.

Referring to FIG. 17, a gate insulating layer GI may be formed on the insulating layer 520′. The gate insulating layer GI may be formed to cover the active layer 530″. The gate insulating layer GI may be formed using an inorganic insulating material.

A gate electrode GAT may be formed on the gate insulating layer GI. The gate electrode GAT may be formed to partially overlap the active layer 530″ in the third direction DR3. The gate electrode GAT may be formed using metal, a metal oxide, a metal nitride, or the like.

An interlayer-insulating layer ILD may be formed on the gate insulating layer GI. The interlayer-insulating layer ILD may be formed to cover the gate electrode GAT. The interlayer-insulating layer ILD may be formed using an inorganic insulating material.

Each of a source electrode SE and a drain electrode DE may be formed on the interlayer-insulating layer ILD. Each of the source electrode SE and the drain electrode DE may be connected to the active layer 530″ through a contact hole. Each of the source electrode SE and the drain electrode DE may be formed using metal, metal oxide, metal nitride, or the like.

Accordingly, a first transistor TFT1, a second transistor TFT2, and a third transistor TFT3 may be formed on the substrate 510. The first transistor TFT1 may include a first active layer 530a″, a first gate electrode GAT1, a first source electrode SE1, and a first drain electrode DE1. The second transistor TFT2 may include a second active layer 530b″, a second gate electrode GAT2, a second source electrode SE2, and a second drain electrode DE2. The third transistor TFT3 may include a third active layer 530c″, a third gate electrode GAT3, a third source electrode SE3, and a third drain electrode DE3.

A via-insulating layer VIA may be formed on the interlayer-insulating layer ILD. The via-insulating layer VIA may be formed to cover the source electrode SE and the drain electrode DE. The via-insulating layer VIA may be formed to have a substantially flat upper surface. The via-insulating layer VIA may be formed using an organic insulating material.

An anode electrode ANO may be formed on the via-insulating layer VIA. The anode electrode ANO may be connected to the drain electrode DE. The anode electrode ANO may be formed using metal, metal oxide, metal nitride, or the like.

A pixel defining layer PDL may be formed on the via-insulating layer VIA. An opening exposing each of a first electrode ANO1, a second electrode ANO2, and a third electrode ANO3 may be formed in the pixel defining layer PDL. The pixel defining layer PDL may be formed using an organic insulating material.

An intermediate layer ML may be formed on the anode electrode ANO. The intermediate layer ML may be formed using an organic material. In the intermediate layer ML, an electron injection layer, an electron transport layer, a light emitting layer, a hole transport layer, and a hole injection layer may be sequentially formed.

A cathode electrode CATH may be formed on the intermediate layer ML. The cathode electrode CATH may include a first cathode electrode CATH1, a second cathode electrode CATH2, and a third cathode electrode CATH3. The first cathode electrode CATH1 may be formed on the first transistor TFT1, the second cathode electrode CATH2 may be formed on the second transistor TFT2, and the third cathode electrode CATH3 may be formed on the third transistor TFT3. Alternatively, the first cathode electrode CATH1, the second cathode electrode CATH2, and the third cathode electrode CATH3 may be formed in a connected form.

Accordingly, a first light emitting device ED1 including the first anode electrode ANO1, a first intermediate layer ML1, and the first cathode electrode CATH1 may be formed on the substrate 510. A second light emitting device ED2 including the second anode electrode ANO2, a second intermediate layer ML2, and the second cathode electrode CATH2 may be formed on the substrate 510. A third light emitting device ED3 including the third anode electrode ANO3, a third intermediate layer ML3, and the third cathode electrode CATH3 may be formed on the substrate 510.

Each of the plurality of light emitting device ED (e.g., each of the first light emitting device ED1, the second light emitting device ED2, and the third light emitting device ED3) may emit same color light. For example, each of the first light emitting device ED1, the second light emitting device ED2, and the third light emitting device ED3 may emit blue light altogether. Alternatively, each of the first light emitting device ED1, the second light emitting device ED2, and the third light emitting device ED3 may emit different color light each other. For example, the first light emitting device ED1 may emit red light, the second light emitting device ED2 may emit green light, and the third light emitting device ED3 may emit the blue light. However, the disclosure is not limited thereto.

A thin film encapsulation layer TFE may be formed on the cathode electrode CATH. The thin film encapsulation layer TFE may include a first inorganic layer IL1, an organic layer OL, and a second inorganic layer IL2. The first inorganic layer IL1, the organic layer OL, and the second inorganic layer IL2 may be sequentially formed. The organic layer OL may be formed to have a relatively thick thickness and a flat top surface compared to the first inorganic layer IL1 and the second inorganic layer IL2. The thin film encapsulation layer TFE may further include additional inorganic layer and/or additional organic layer.

Accordingly, the display device DD as shown in FIG. 11 may be manufactured.

According to the laser annealing method according to an embodiment of the disclosure and the manufacturing method of the display device using the same, the occurrence of the film bursting defect may be effectively prevented by applying the cumulative temperature reduction pulse profile (e.g., the pulse profile PP of FIG. 2), and the yield of the display device DD may be enhanced.

The laser annealing device in the embodiments may be applied to a display device included in a computer, a notebook, a mobile phone, a smartphone, a smart pad, a portable media player (“PMP”), a personal digital assistance (“PDA”), an MP3 player, or the like.

Although the embodiments have been described with reference to the drawings, the illustrated embodiments are examples, and may be modified and changed by a person having ordinary knowledge in the relevant technical field without departing from the technical spirit described in the following claims.

What is claimed is:

1. A laser annealing device including:
a controller configured to form a pulse profile sequentially including a first peak having a first intensity, a second peak having a second intensity greater than the first intensity, and a third peak having a third intensity between the first intensity and the second intensity by selecting an output time of a plurality of pulses such that the plurality of pulses overlap in the output time; and
a laser generator configured to sequentially output the plurality of pulses.

2. The laser annealing device of claim 1, wherein,
the laser generator is provided in plurality, and grouped into a first laser group, a second laser group, and a third laser group, and
the first laser group includes only one laser generator.

3. The laser annealing device of claim 2, wherein,
the first laser group is configured to output a first pulse,
the second laser group is configured to sequentially output, following the first pulse, a second pulse, a third pulse, a fourth pulse, a fifth pulse, a sixth pulse, a seventh pulse, and an eighth pulse,
the third laser group is configured to sequentially output, following the eighth pulse, a ninth pulse and a tenth pulse,
the first peak is formed by the first pulse,
the second peak is formed by overlapping the second pulse, the third pulse, the fourth pulse, the fifth pulse, the sixth pulse, the seventh pulse, and the eighth pulse in the output time, and
the third peak is formed by overlapping the ninth pulse and the tenth pulse in the output time.

4. The laser annealing device of claim 3, wherein a time interval between the eighth pulse and the ninth pulse is greater than 0 and about 12 nanoseconds or less.

5. The lase annealing device of claim 3, wherein,
a time interval between the first pulse and the ninth pulse is about 91 to about 95 nanoseconds, and
a time interval between the first pulse and the tenth pulse is about 101 to about 105 nanoseconds.

6. The laser annealing device of claim 3, wherein a time interval between the ninth pulse and the tenth pulse is set to be greater than any of a time interval between two adjacent pulses among the second to eighth pulses.

7. The laser annealing device of claim 1,
wherein an object to be processed by the plurality of pulses includes:
a substrate;
a first insulating layer disposed on the substrate and having a first hydrogen content;
a second insulating layer disposed on the first insulating layer and having a second hydrogen content smaller than the first hydrogen content; and
a preliminary active layer disposed on the second insulating layer and including amorphous silicon.

8. The laser annealing device of claim 7, wherein,
a temperature profile of the preliminary active layer corresponding to the pulse profile includes a fourth peak and a fifth peak,
a temperature of the fifth peak is greater than a temperature of the fourth peak, and
a temperature of the preliminary active layer gradually decreases over time starting from the fifth peak.

9. The laser annealing device of claim 1, wherein the laser generator includes a solid laser medium.

10. The annealing device of claim 1, wherein the plurality of pulses have a same pulse width and same intensity.

11. A laser annealing method, the method including:
forming a pulse profile sequentially including a first peak having a first intensity, a second peak having a second intensity greater than the first intensity, and a third peak having a third intensity between the first intensity and the second intensity by selecting an output time of the plurality of pulses such that a plurality of pulses overlap in the output time;
sequentially outputting the plurality of pulses to an object to be processed, which includes amorphous silicon; and
annealing the amorphous silicon into polysilicon.

12. The method of claim 11, wherein,
the first is formed by a first pulse,
the second peak is formed by overlapping a second pulse, a third pulse, a fourth pulse, a fifth pulse, a sixth pulse, a seventh pulse, and an eighth pulse in the output time, and
the third peak is formed by overlapping a ninth pulse and a tenth pulse in the output time.

13. The method of claim 12, wherein the ninth pulse is output to have a time interval greater than 0 and less than about 12 nanoseconds from the eighth pulse.

14. The method of claim 12, wherein,
the ninth pulse is output to have a time interval of about 91 to about 95 nanoseconds from the first pulse, and
the tenth pulse is output to have a time interval of about 101 to about 105 nanoseconds from the first pulse.

15. The method of claim 12,
wherein the object to be processed includes:
a substrate;
a first insulating layer having a first hydrogen content formed on the substrate;
a second insulating layer formed on the first insulating layer and having a second hydrogen content smaller than the first hydrogen content; and
a preliminary active layer formed of the amorphous silicon on the second insulating layer.

16. The method of claim 15,
wherein the first insulating layer is formed of silicon nitride, and
the second insulating layer is formed of silicon oxide.

17. The method of claim 15, wherein a time interval between the ninth pulse and the tenth pulse is set to be greater than any of a time interval between two adjacent pulses among the second to eighth pulses.

18. The method of claim 11,
wherein the forming of the pulse profile comprises:
the first intensity and the third intensity are selected to correspond to a temperature less than a melting temperature of the amorphous silicon, and
the second intensity is selected to correspond to a temperature greater than the melting temperature of the amorphous silicon.

19. The method of claim 11, wherein the plurality of pulses are generated using a solid laser medium.

20. The method of claim 11, wherein the plurality of pulses are set to have a same pulse width and same intensity.
